(19) United States
(12) Patent Application Publication
(10) Pub. No.: US 2026/0140153 A1
(43) Pub. Date: May 21, 2026

(54) RADIO FREQUENCY POWER DETECTION DEVICE AND SYSTEM

(71) Applicant: SHENZHEN RSPOWER TECHNOLOGY CO., LTD., Shenzhen (CN)

(72) Inventors: Shuxiao WANG, Shenzhen (CN); Yati CHEN, Shenzhen (CN)

(21) Appl. No.: 19/449,901

(22) Filed: Jan. 15, 2026

Related U.S. Application Data
(63) Continuation of application No. PCT/CN2024/108601, filed on Jul. 30, 2024.

(30) Foreign Application Priority Data
Dec. 26, 2023 (CN) 202311799201.8

(51) Int. Cl. G01R 21/00; G01R 19/00; H01G 5/06; H01P 3/08

(52) U.S. Cl. CPC G01R 21/001; G01R 19/0084; H01G 5/06; H01P 3/081

(57) ABSTRACT

A radio frequency power detection device and a radio frequency power detection system are provided. The radio frequency power detection device includes a first microstrip line, a second microstrip line, a voltage detection unit, a capacitor unit, and a distance testing unit. The first microstrip line is connected to a radio frequency power supply. The second microstrip line is disposed parallel to the first microstrip line and coupled to the first microstrip line, and a predetermined point on the second microstrip line is grounded. The voltage detection unit is connected to one end of the second microstrip line and is configured to detect a voltage of the second microstrip line. The capacitor unit is connected to the first microstrip line and the second microstrip line, or the predetermined point on the second microstrip line is grounded through the capacitor unit.

This application is a continuation of International Application No. PCT/CN2024/108601, filed Jul. 30, 2024, which claims priority to Chinese Patent Application No. 202311799201.8, filed Dec. 26, 2023, the entire disclosures of both of which are incorporated herein by reference.

### TECHNICAL FIELD

The disclosure relates to the field of radio frequency circuit technology, and in particular, to a radio frequency power detection device and a radio frequency power detection system.

### BACKGROUND

During production, a microstrip line is intended to have a physical isolation point grounded at one end, where the physical isolation point exhibits a voltage of 0 V. However, during actual production, the distance between microstrip lines may not be accurate, resulting in the grounded point on the microstrip line not being the intended physical isolation point. Consequently, the voltage of the microstrip line cannot be accurately detected, and thus the radio frequency power may not be accurately calculated.

### SUMMARY

In a first aspect, a radio frequency power detection device is provided in embodiments of the disclosure. The radio frequency power detection device includes a first microstrip line, a second microstrip line, a voltage detection unit, a capacitor unit, and a distance testing unit. The first microstrip line is connected to a radio frequency power supply. The second microstrip line is disposed parallel to the first microstrip line and coupled to the first microstrip line, a predetermined point on the second microstrip line is grounded, and the predetermined point is used to indicate a physical isolation point of the second microstrip line. The voltage detection unit is connected to one end of the second microstrip line and is configured to detect a voltage of the second microstrip line. The capacitor unit includes a capacitor sub-unit and a control sub-unit. The capacitor sub-unit is connected to the control sub-unit, and the control sub-unit is configured to control an output capacitance value of the capacitor unit based on the capacitor sub-unit. The capacitor unit is connected to the first microstrip line and the second microstrip line, or the predetermined point on the second microstrip line is grounded through the capacitor unit. The capacitor unit is configured to select different capacitance values according to an actual distance between the first microstrip line and the second microstrip line, to make the actual distance between the first microstrip line and the second microstrip line equal to a preset distance between the first microstrip line and the second microstrip line. The distance testing unit is connected to the capacitor unit and the voltage detection unit, and the distance testing unit is configured to detect a voltage at the predetermined point. The distance testing unit is configured to send a first distance signal to the control sub-unit based on the voltage at the predetermined point being greater than zero, send a second distance signal to the control sub-unit based on the voltage at the predetermined point being less than zero, and send a third distance signal to the voltage detection unit based on the voltage at the predetermined point being zero. The first distance signal is used to indicate that the actual distance is less than the preset distance, the second distance signal is used to indicate that the actual distance is greater than the preset distance, and the third distance signal is used to indicate that the actual distance is equal to the preset distance.

In a second aspect, a radio frequency power detection system is provided in embodiments of the disclosure. The radio frequency power detection system includes the radio frequency power detection device of the first aspect and a radio frequency power supply. The radio frequency power supply is connected to the radio frequency power detection device.

### BRIEF DESCRIPTION OF THE DRAWINGS

FIG. 1 is a system architecture diagram of a radio frequency power detection system provided in an embodiment of the disclosure.

FIG. 2 is a structural diagram of a first type of radio frequency power detection device provided in an embodiment of the disclosure.

FIG. 3 is a structural diagram of a second type of radio frequency power detection device provided in an embodiment of the disclosure.

FIG. 4 is a structural diagram of a capacitor unit in a radio frequency power detection device provided in an embodiment of the disclosure.

FIG. 5 is a positional structure diagram of a first type of capacitor unit in a radio frequency power detection device provided in an embodiment of the disclosure.

FIG. 6 is a positional structure diagram of a second type of capacitor unit in a radio frequency power detection device provided in an embodiment of the disclosure.

FIG. 7 is a positional structure diagram of a third type of capacitor unit in a radio frequency power detection device provided in an embodiment of the disclosure.

FIG. 8 is a structural diagram of a third type of radio frequency power detection device provided in an embodiment of the disclosure.

### DETAILED DESCRIPTION

For those of ordinary skill in the art to better understand the disclosure, the following will clearly and comprehensively illustrate technical solutions of embodiments of the disclosure with reference to the accompanying drawings of embodiments of the disclosure. Apparently, embodiments described herein are merely some embodiments, rather than all embodiments, of the disclosure. Based on the embodiments of the disclosure, all other embodiments obtained by those of ordinary skill in the art without creative effort shall fall within the protection scope of the disclosure.

The terms “first”, “second”, and the like in the specification, claims of the disclosure, and the above accompanying drawings are used for distinguishing different objects, rather than for describing a specific order. In addition, the terms “include”, “have”, and any variations thereof are intended to cover non-exclusive inclusions. For example, a process, method, system, product, or apparatus that includes a series of steps or units is not limited to the listed steps or units, but optionally further includes steps or units not listed, or optionally further includes other steps or units inherent to the process, method, product, or apparatus.

Reference to “embodiment” herein means that a particular feature, structure, or characteristic described in conjunction with the embodiment may be included in at least one embodiment of the present disclosure. The presence of the term at each place in the specification does not necessarily refer to the same embodiment, nor does it refer to a separate or alternative embodiment that is mutually exclusive of other embodiments. It may be understood by those skilled in the art, both explicitly and implicitly, that the embodiments described herein may be combined with other embodiments.

At present, during actual production, the distance between microstrip lines may not be accurate, resulting in the grounded point on a microstrip line not being the intended physical isolation point. Consequently, the voltage of the microstrip line cannot be accurately detected, and thus the radio frequency power may not be accurately calculated.

Reference is made to FIG. 1, which is a system architecture diagram of a radio frequency power detection system provided in an embodiment of the disclosure. As illustrated in FIG. 1, a radio frequency power detection system 100 includes a radio frequency power detection device 10 and a radio frequency power supply 20. The radio frequency power detection device 10 is connected to the radio frequency power supply 20. When the radio frequency power supply 20 supplies power to a first microstrip line in the radio frequency power detection device 10, a second microstrip line in the radio frequency power detection device 10 will be subjected to the dual effects of the magnetic field and the electric field. The magnetic field intensity exhibits a positive value at one end of the second microstrip line and a negative value at the other end of the second microstrip line. Therefore, the second microstrip line has a point where the magnetic field intensity is zero. In this case, in order to ensure that the grounded point on the microstrip line is the physical isolation point with a voltage of 0 V, it is necessary to adjust a capacitance value of a capacitor unit in the radio frequency power detection device 10 to adjust the distance between the first microstrip line and the second microstrip line. With the adjustment, an actual distance between the first microstrip line and the second microstrip line is made to be equal to a preset distance between the first microstrip line and the second microstrip line. Consequently, the voltage of the second microstrip line may be detected, so as to calculate the radio frequency power, thereby improving the accuracy of voltage detection for the radio frequency power supply.

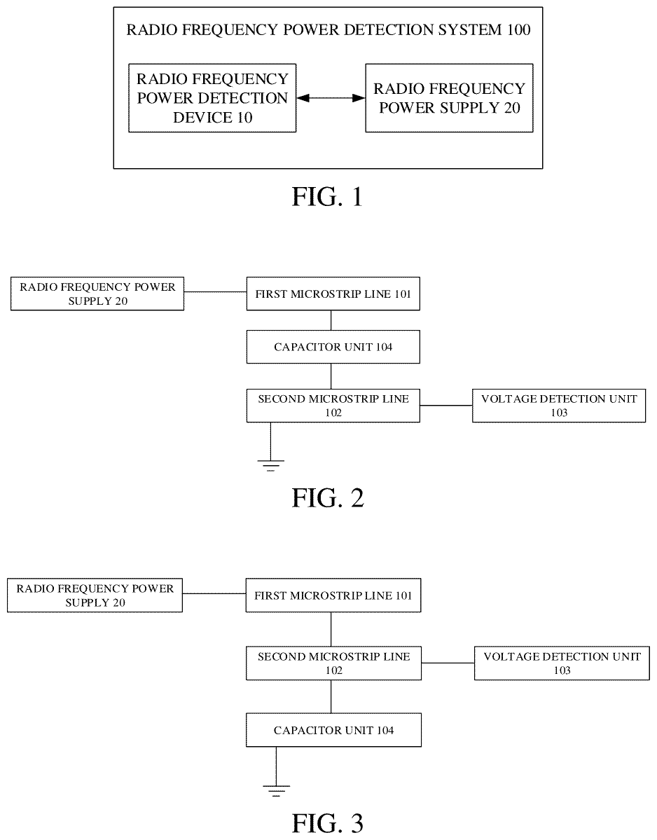

Reference is made to FIG. 2 and FIG. 3. FIG. 2 is a structural diagram of a first type of the radio frequency power detection device provided in an embodiment of the disclosure. FIG. 3 is a structural diagram of a second type of the radio frequency power detection device provided in an embodiment of the disclosure. As illustrated in FIG. 2, the radio frequency power detection device 10 includes a first microstrip line 101, a second microstrip line 102, a voltage detection unit 103, and a capacitor unit 104. The first microstrip line 101 is connected to a radio frequency power supply 20. The second microstrip line 102 is disposed parallel to the first microstrip line 101 and coupled to the first microstrip line 101. A predetermined point on the second microstrip line 102 is grounded, and the predetermined point is used to indicate a physical isolation point of the second microstrip line 102. The voltage detection unit 103 is connected to one end of the second microstrip line 102 and is configured to detect the voltage of the second microstrip line 102. The capacitor unit 104 is connected to the first microstrip line 101 and the second microstrip line 102. The capacitor unit 104 is configured to select different capacitance values according to an actual distance between the first microstrip line 101 and the second microstrip line 102, to make the actual distance between the first microstrip line 101 and the second microstrip line 102 equal to the preset distance between the first microstrip line 101 and the second microstrip line 102. As illustrated in FIG. 3, the radio frequency power detection device includes the first microstrip line 101, the second microstrip line 102, the voltage detection unit 103, and the capacitor unit 104. The first microstrip line 101 is connected to the radio frequency power supply 20. The second microstrip line 102 is disposed parallel to the first microstrip line 101 and coupled to the first microstrip line 101. A predetermined point on the second microstrip line 102 is grounded, and the predetermined point is used to indicate a physical isolation point of the second microstrip line 102. The voltage detection unit 103 is connected to one end of the second microstrip line 102 and is configured to detect the voltage of the second microstrip line 102. The predetermined point on the second microstrip line is grounded through the capacitor unit 104. The capacitor unit 104 is configured to select different capacitance values according to the actual distance between the first microstrip line 101 and the second microstrip line 102, to make the actual distance between the first microstrip line 101 and the second microstrip line 102 equal to the preset distance between the first microstrip line 101 and the second microstrip line 102. Therefore, the voltage of the second microstrip line 102 is detected, and the radio frequency power is calculated, thereby improving the accuracy of voltage detection for the radio frequency power supply 20.

The radio frequency power supply 20 supplies power to the first microstrip line 101. Affected by the current, the second microstrip line 102 is subjected to the dual effects of the magnetic field and the electric field. In this case, for a certain point on the second microstrip line 102, an electric field value is: ΔF×d, and a magnetic field value is:

$$\frac{μ}{ε} \times \frac{l}{d} Δ I .$$

ΔE is the electric field intensity at a certain point on the first microstrip line 101, d is the preset distance between the first microstrip line 101 and the second microstrip line 102, μ is the magnetic permeability, ε is the permittivity, l is the length of the second microstrip line 102, and ΔI is the current of the first microstrip line 101. At one end of the second microstrip line 102, the electric field intensity and the magnetic field intensity are equal in magnitude and the same in direction. At the other end of the second microstrip line 102, the electric field intensity and the magnetic field intensity are equal in magnitude but opposite in direction.

Therefore, d may be determined according to the above equation, as follows:

$${d}^{2} = \frac{μ}{ε} \times \frac{l}{R} .$$

R is the main circuit resistance. Based on the magnetic field intensity being positive at one end and negative at the other end, a grounded point with the magnetic field intensity being zero exists on the second microstrip line 102. The point is the physical isolation point. However, there is a difference between the preset distance d and an actual distance d1. As illustrated in FIG. 2, the capacitor unit 104 may be added between the first microstrip line 101 and the second microstrip line 102 using a voltage division method. The capacitor unit 104 may include multiple capacitors, or a variable capacitor, or a programmable capacitor, such that different capacitance values may be selected according to the difference between the preset distance d and the actual distance d1, thereby finding a suitable distance. In this case, a microstrip voltage detected at the physical isolation point is 0 V, enabling accurate detection of the voltage of the second microstrip line 102. The radio frequency power is then calculated according to the voltage of the second microstrip line 102. As illustrated in FIG. 3, the predetermined point on the second microstrip line 102 may be grounded through the capacitor unit 104 using a voltage division method. The capacitor unit 104 may include multiple capacitors, or a variable capacitor, or a programmable capacitor, such that different capacitance values may be selected according to the difference between the preset distance d and the actual distance d1, thereby finding a suitable distance. In this case, a microstrip voltage detected at the physical isolation point is 0 V, enabling accurate detection of the voltage of the second microstrip line 102. The radio frequency power is then calculated according to the voltage of the second microstrip line 102, thereby improving the accuracy of voltage detection for the radio frequency power supply 20.

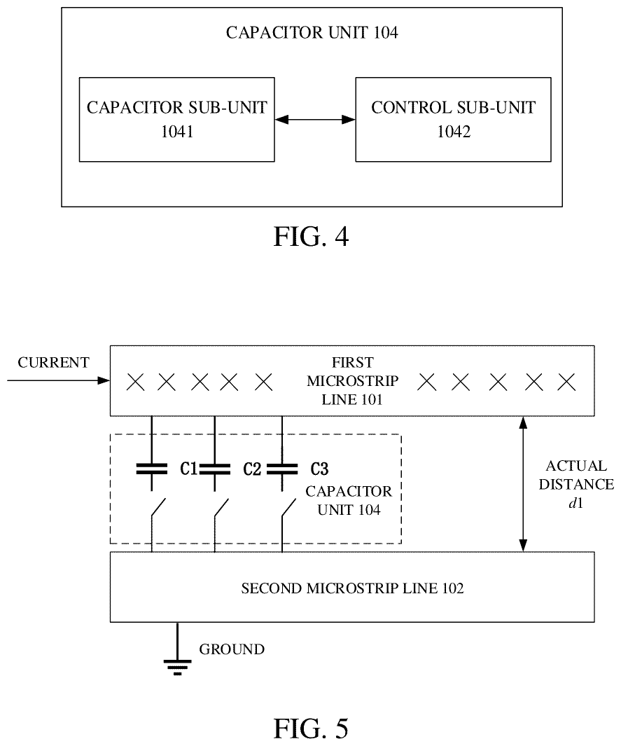

In a possible embodiment, reference is made to FIG. 4, which is a structural diagram of a capacitor unit in a radio frequency power detection device provided in an embodiment of the disclosure. As illustrated in FIG. 4, the capacitor unit 104 includes a capacitor sub-unit 1041 and a control sub-unit 1042. The capacitor sub-unit 1041 is connected to the control sub-unit 1042. The control sub-unit 1042 is configured to control an output capacitance value of the capacitor unit 104 based on the capacitor sub-unit 1041.

The capacitor sub-unit 1041 may include multiple capacitors, or a variable capacitor, or a programmable capacitor, etc. The control sub-unit 1042 is configured to control the above capacitors to change the output capacitance value of the capacitor unit 104. Reference is made to FIG. 5, which is a positional structure diagram of a first type of the capacitor unit in the radio frequency power detection device provided in an embodiment of the disclosure. As illustrated in FIG. 5, the capacitor unit 104 is connected to the first microstrip line 101 and the second microstrip line 102. The first microstrip line 101 is powered. The second microstrip line 102 is disposed parallel to the first microstrip line 101 and coupled to the first microstrip line 101. A predetermined point on the second microstrip line 102 is grounded, and the predetermined point is used to indicate the physical isolation point of the second microstrip line 102. On condition that the capacitor sub-unit 1041 includes multiple capacitors, the multiple capacitors are connected in parallel. Exemplarily, there may be a capacitor C1, a capacitor C2, and a capacitor C3, and the number of the capacitors is not limited herein. The control sub-unit 1042 may further include at least one switch. The at least one switch is connected to each of the multiple capacitors, enabling the control sub-unit 1042 to control the connection and disconnection between each of the multiple capacitors and the second microstrip line 102 based on the at least one switch. The capacitance value of each capacitor in the multiple capacitors may be different, so as to facilitate the control sub-unit 1042 in selecting an appropriate capacitance value according to the difference between the preset distance d and the actual distance d1. The switch for the multiple capacitors may be a single-pole multi-throw switch. Alternatively, each capacitor in the multiple capacitors may be connected to one switch. Alternatively, a combination of the above two methods may be adopted. That is, for some capacitors in the multiple capacitors, each capacitor is connected to one switch, and the remaining capacitors in the multiple capacitors are connected to at least one single-pole multi-throw switch. The multiple capacitors may also be disposed between the second microstrip line 102 and a ground terminal.

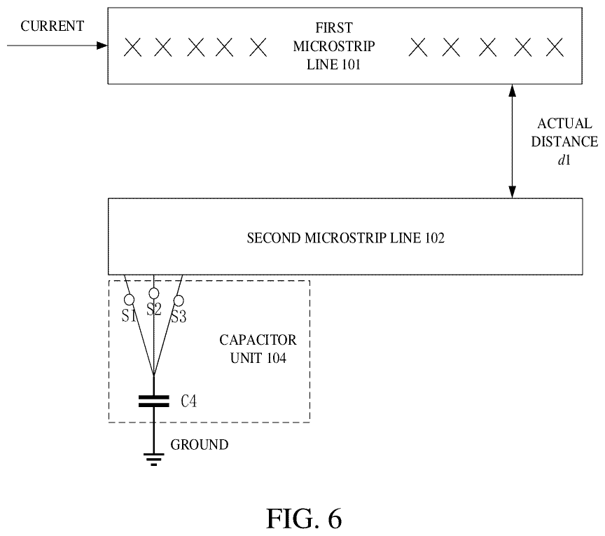

Reference is made to FIG. 6, which is a positional structure diagram of a second type of the capacitor unit in the radio frequency power detection device provided in an embodiment of the disclosure. As illustrated in FIG. 6, the predetermined point on the second microstrip line 102 is grounded through the capacitor unit 104. The first microstrip line 101 is powered. The second microstrip line 102 is disposed parallel to the first microstrip line 101 and coupled to the first microstrip line 101. The predetermined point on the second microstrip line 102 is grounded, and the predetermined point is used to indicate the physical isolation point of the second microstrip line 102. On condition that the capacitor sub-unit 1041 includes a variable capacitor C4, the variable capacitor C4 may include a first electrode plate and a second electrode plate. The first electrode plate and the second electrode plate are mutually insulated, and the first electrode plate is grounded. The control sub-unit 1042 includes at least one capacitor adjuster. Exemplarily, the control sub-unit 1042 may include a capacitor adjuster S1, a capacitor adjuster S2, and a capacitor adjuster S3. The capacitor adjuster S1, the capacitor adjuster S2, and the capacitor adjuster S3 are connected to the variable capacitor C4. Each capacitor adjuster corresponds to a different capacitance-value range. The control sub-unit 1042 is configured to select a capacitor adjuster according to the difference between the preset distance d and the actual distance d1, and control rotation of the first electrode plate to change the capacitance value within the capacitance-value range corresponding to the selected capacitor adjuster, so as to make the preset distance d is equal to the actual distance d1.

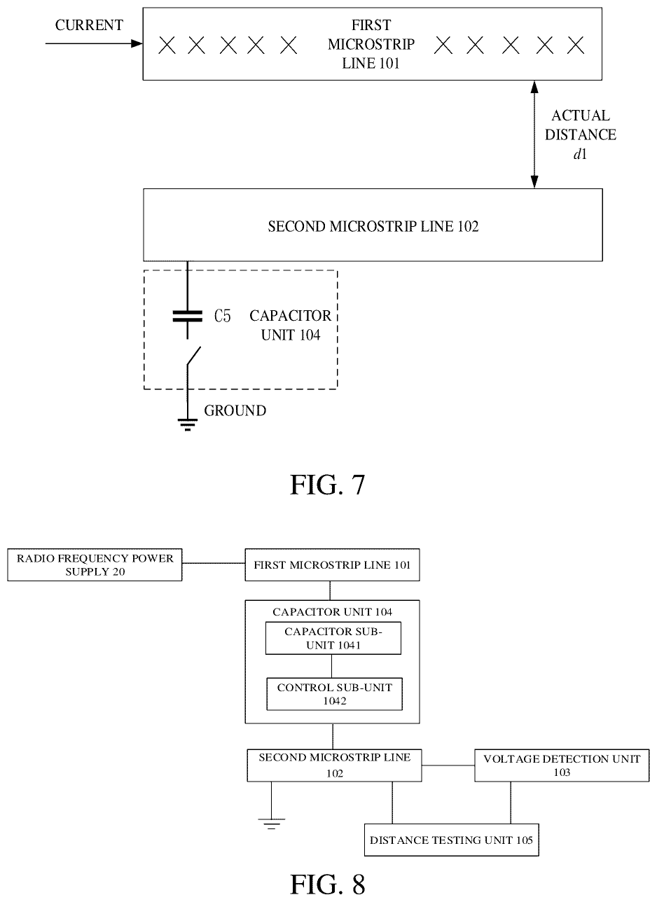

Reference is made to FIG. 7, which is a positional structure diagram of a third type of the capacitor unit in the radio frequency power detection device provided in an embodiment of the disclosure. As illustrated in FIG. 7, the predetermined point on the second microstrip line 102 is grounded through the capacitor unit 104. The first microstrip line 101 is powered. The second microstrip line 102 is disposed parallel to the first microstrip line 101 and coupled to the first microstrip line 101. The predetermined point on the second microstrip line 102 is grounded, and the predetermined point is used to indicate the physical isolation point of the second microstrip line 102. On condition that the capacitor sub-unit 1041 includes a programmable capacitor C5, the programmable capacitor C5 is configured with a capacitance-value control logic. The control sub-unit 1042 is configured to generate a capacitance-value control signal according to the difference between the preset distance d and the actual distance d1. The programmable capacitor C5 is configured to control the capacitance value of the programmable capacitor C5 by inputting a required capacitance value based on the capacitance-value control logic in response to the capacitance-value control signal. The programmable capacitor C5 may also be disposed between the first microstrip line 101 and the second microstrip line 102.

It may be seen that, in this embodiment, the capacitance value of the capacitor sub-unit 1041 may be controlled by the control sub-unit 1042, thereby adjusting the distance between the first microstrip line 101 and the second microstrip line 102, which facilitates a more accurate calculation of the radio frequency power.

In a possible embodiment, the capacitor sub-unit 1041 includes multiple capacitors, and the multiple capacitors are connected in parallel. The control sub-unit 1042 includes at least one switch, the at least one switch is connected to each of the multiple capacitors, and a connection state between each of the multiple capacitors and the second microstrip line 102 is controlled based on the at least one switch. The connection state includes a normal connection or a disconnection.

The capacitance value of each capacitor in the multiple capacitors may be the same, or may be different. There is at least one capacitor having the capacitance value different from the capacitance values of other capacitors, so as to facilitate the control sub-unit 1042 in selecting an appropriate capacitance value according to the difference between the preset distance d and the actual distance d1. The switch for the multiple capacitors may be a single-pole multi-throw switch. Alternatively, each capacitor in the multiple capacitors may be connected to one switch. Alternatively, a combination of the above two methods may be adopted. That is, for some capacitors in the multiple capacitors, each capacitor is connected to one switch, and the remaining capacitors in the multiple capacitors are connected to at least one single-pole multi-throw switch. The multiple capacitors may be disposed between the second microstrip line 102 and the ground terminal, and may also be disposed between the second microstrip line 102 and the first microstrip line 101. The capacitance value is adjusted by controlling the switch for the multiple capacitors through the control unit 1042.

It may be seen that, in this embodiment, the capacitance value is adjusted by controlling the switch for the multiple capacitors through the control sub-unit 1042, facilitating a more accurate control of the capacitance value.

In a possible embodiment, the radio frequency power detection device 10 further includes a distance testing unit 105. The distance testing unit 105 is connected to the capacitor unit 104 and the voltage detection unit 103. The distance testing unit 105 is configured to detect the voltage at the predetermined point. The distance testing unit is further configured to send a first distance signal to the control sub-unit 1042 based on the voltage at the predetermined point being greater than zero, send a second distance signal to the control sub-unit 1042 based on the voltage at the predetermined point being less than zero, and send a third distance signal to the voltage detection unit 103 based on the voltage at the predetermined point being zero. The first distance signal is used to indicate that the actual distance is less than the preset distance, the second distance signal is used to indicate that the actual distance is greater than the preset distance, and the third distance signal is used to indicate that the actual distance is equal to the preset distance.

Reference is made to FIG. 8, which is a structural diagram of a third type of the radio frequency power detection device provided in an embodiment of the disclosure. As illustrated in FIG. 8, the radio frequency power detection device 10 further includes the distance testing unit 105. The distance testing unit 105 is connected to the capacitor unit 104 and the voltage detection unit 103. The distance testing unit 105 is configured to detect the voltage at the predetermined point. The capacitor unit 104 is connected to the first microstrip line 101 and the second microstrip line 102. The first microstrip line 101 is powered. The second microstrip line 102 is disposed parallel to the first microstrip line 101 and coupled to the first microstrip line 101. The predetermined point on the second microstrip line 102 is grounded, and the predetermined point is used to indicate the physical isolation point of the second microstrip line 102. The voltage detection unit 103 is connected to one end of the second microstrip line 102 and is configured to detect the voltage of the second microstrip line 102. When the distance testing unit 105 receives a voltage test signal from the voltage detection unit 103, the distance testing unit 105 detects the voltage at the predetermined physical isolation point in response to the voltage test signal. On condition that the detected voltage is greater than zero, the distance testing unit 105 sends to the control sub-unit 1042 a signal indicating that the actual distance d1 is less than the preset distance d. Upon receiving the signal, the control sub-unit 1042 adjusts the capacitance value of the capacitor(s) in the capacitor sub-unit 1041 according to the current capacitance value, to make the actual distance d1 equal to the preset distance d. On condition that the detected voltage is less than zero, the distance testing unit 105 sends to the control sub-unit 1042 a signal indicating that the actual distance d1 is greater than the preset distance d. Upon receiving the signal, the control sub-unit 1042 adjusts the capacitance value of the capacitor(s) in the capacitor sub-unit 1041 according to the current capacitance value, to make the actual distance d1 equal to the preset distance d. On condition that the detected voltage is equal to zero, the distance testing unit 105 sends to the voltage detection unit 103 a signal indicating that the actual distance d1 is equal to the preset distance d, thereby instructing the voltage detection unit 103 to detect the voltage of the second microstrip line 102 to calculate the radio frequency power.

It may be seen that, in this embodiment, the actual distance between the first microstrip line 101 and the second microstrip line 102 is obtained through the distance testing unit 105, and a distance signal is sent to the control sub-unit 1042 and the voltage detection unit 103 according to the actual distance and the preset distance. Therefore, the control sub-unit 1042 may adjust the capacitance value based on the distance signal, and the voltage detection unit 103 may accurately detect the voltage of the second microstrip line 102.

In a possible embodiment, based on the predetermined point on the second microstrip line 102 being grounded through the capacitor unit 104, the capacitor sub-unit 1041 includes a variable capacitor. The variable capacitor includes a first electrode plate and a second electrode plate, and the first electrode plate and the second electrode plate are mutually insulated. The first electrode plate is grounded, and the control sub-unit 1042 is configured to control rotation of the first electrode plate to control the capacitance value of the variable capacitor.

On condition that the capacitor sub-unit 1041 includes the variable capacitor C4, the variable capacitor may include the first electrode plate and the second electrode plate. The first electrode plate and the second electrode plate are mutually insulated, and the first electrode plate is grounded. The first electrode plate may be a rotor, and the second electrode plate may be a stator. The capacitance value may be adjusted by adjusting the rotation angle of the rotor relative to the stator. A greater rotation angle corresponds to a greater capacitance value.

It may be seen that, in this embodiment, the capacitance value of the variable capacitor is changed by adjusting the rotation angle of the first electrode plate. The operation is simple and allows for a more accurate adjustment of the capacitance value.

In a possible embodiment, the control sub-unit 1042 includes at least one capacitor adjuster, each of the at least one capacitor adjuster is connected to the variable capacitor, and the control sub-unit 1042 is configured to control rotation of the first electrode plate based on the at least one capacitor adjuster.

Reference is made to FIG. 6 and FIG. 8. The control sub-unit 1042 includes at least one capacitor adjuster. Exemplarily, the control sub-unit 1042 may include the capacitor adjuster S1, the capacitor adjuster S2, and the capacitor adjuster S3. The capacitor adjuster S1, the capacitor adjuster S2, and the capacitor adjuster S3 are connected to the variable capacitor. Each capacitor adjuster corresponds to a different capacitance-value range. The control sub-unit 1042 is configured to select a capacitor adjuster according to the first distance signal or the second distance signal, and control rotation of the first electrode plate to change the capacitance value within the capacitance-value range corresponding to the selected capacitor adjuster, so as to make the preset distance d is equal to the actual distance d1.

It may be seen that, in this embodiment, a capacitor adjuster is selected according to requirements, and rotation of the first electrode plate is controlled to change the capacitance value within the capacitance-value range corresponding to the selected capacitor adjuster, achieving accurate adjustment of the capacitance value.

In a possible embodiment, the capacitor sub-unit 1041 includes a programmable capacitor. The programmable capacitor is configured with a capacitance-value control logic. The control sub-unit 1042 is configured to generate a capacitance-value control signal according to the first distance signal or the second distance signal, and the programmable capacitor is configured to control the capacitance value of the programmable capacitor based on the capacitance-value control logic in response to the capacitance-value control signal.

Reference is made to FIG. 7 and FIG. 8. The capacitor sub-unit 1041 includes the programmable capacitor C5. The programmable capacitor C5 is configured with a capacitance-value control logic. The control sub-unit 1042 is configured to generate a capacitance-value control signal according to the first distance signal or the second distance signal. The programmable capacitor C5 is configured to control the capacitance value of the programmable capacitor based on the capacitance-value control logic in response to the capacitance-value control signal. A required capacitance value may be input according to the current capacitance value and the received distance signal to control the capacitance value of the programmable capacitor. The programmable capacitor C5 may also be disposed between the first microstrip line 101 and the second microstrip line 102.

It may be seen that, in this embodiment, with the programmable capacitor, the required capacitance value to be adjusted to may be directly input, simplifying the operations of adjusting the capacitance value and achieving accurate adjustment of the capacitance value.

In a possible embodiment, based on the capacitor unit 104 being connected to the first microstrip line 101 and the second microstrip line 102, the control sub-unit 1042 is configured to generate a first control strategy according to the first distance signal or the second distance signal. Based on the predetermined point on the second microstrip line 102 being grounded through the capacitor unit 104, the control sub-unit 1042 is configured to generate a second control strategy according to the first distance signal or the second distance signal.

When the capacitor unit 104 is disposed between the first microstrip line 101 and the second microstrip line 102, a greater capacitance value corresponds to a shorter distance between the first microstrip line 101 and the second microstrip line 102. When the capacitor unit 104 is disposed between the second microstrip line 102 and the ground terminal, a greater capacitance value corresponds to a greater distance between the first microstrip line 101 and the second microstrip line 102.

When the capacitor unit 104 is disposed between the first microstrip line 101 and the second microstrip line 102, if the control sub-unit 1042 receives the first distance signal, the first control strategy may include the following. The control sub-unit 1042 is configured to adjust the capacitance value as needed according to the capacitance values of the multiple capacitors and the current capacitance value. If the control sub-unit 1042 detects that the current capacitance value is relatively large and is insufficient to make the actual distance equal to the preset distance, a switch(es) for capacitors is turned off appropriately to reduce the capacitance value, thereby increasing the actual distance between the first microstrip line 101 and the second microstrip line 102 to make the actual distance equal to the preset distance. If the control sub-unit 1042 receives the second distance signal, the first control strategy may further include the following. The control sub-unit 1042 is configured to adjust the capacitance value as needed according to the capacitance values of the multiple capacitors and the current capacitance value. If the control sub-unit 1042 detects that the current capacitance value is relatively small and is insufficient to make the actual distance equal to the preset distance, a switch(es) for capacitors is turned on appropriately to increase the capacitance value, thereby reducing the actual distance between the first microstrip line 101 and the second microstrip line 102 to make the actual distance equal to the preset distance. The first control strategy may also involve adjusting the capacitance value of the programmable capacitor as needed according to the current capacitance value and the received distance signal, to make the actual distance equal to the preset distance.

When the capacitor unit 104 is disposed between the second microstrip line 102 and the ground terminal, if the control sub-unit 1042 receives the first distance signal, the second control strategy may include the following. The control sub-unit 1042 is configured to adjust the capacitance value as needed according to the capacitance values of the multiple capacitors and the current capacitance value. If the control sub-unit 1042 detects that the current capacitance value is relatively large and is insufficient to make the actual distance equal to the preset distance, a switch(es) for capacitors is turned on appropriately to increase the capacitance value, thereby increasing the actual distance between the first microstrip line 101 and the second microstrip line 102 to make the actual distance equal to the preset distance. If the control sub-unit 1042 receives the second distance signal, the second control strategy may further include the following. The control sub-unit 1042 is configured to adjust the capacitance value as needed according to the capacitance values of the multiple capacitors and the current capacitance value. If the control sub-unit 1042 detects that the current capacitance value is relatively small and is insufficient to make the actual distance equal to the preset distance, a switch(es) for capacitors is turned off appropriately to reduce the capacitance value, thereby reducing the actual distance between the first microstrip line 101 and the second microstrip line 102 to make the actual distance equal to the preset distance. If the control sub-unit 1042 receives the first distance signal or the second distance signal, the second control strategy may also include the following. The control sub-unit 1042 selects a capacitor adjuster as needed according to the current capacitance value, and rotates the first electrode plate by a certain angle to adjust the capacitance value within the capacitance-value range corresponding to the selected capacitor adjuster, to make the actual distance equal to the preset distance. A greater rotation angle corresponds to a greater capacitance value. The second control strategy may also involve adjusting the capacitance value of the programmable capacitor as needed according to the current capacitance value and the received distance signal, to make the actual distance equal to the preset distance.

It may be seen that, in this embodiment, the capacitance value may be adjusted directly according to the first control strategy and the second control strategy, facilitating accurate adjustment of the capacitance value.

In a possible embodiment, the capacitance value of at least one capacitor in the multiple capacitors is different from capacitance values of other capacitors.

The capacitance value of each capacitor in the multiple capacitors may be the same or may be different, but at least one capacitor has a capacitance value different from the capacitance values of other capacitors, facilitating the control sub-unit 1042 in selecting an appropriate capacitor according to the difference between the preset distance d and the actual distance d1.

It may be noted that, for the sake of brevity, the foregoing method embodiments are described as a series of action combinations. However, it will be appreciated by those skilled in the art that the disclosure is not limited by the sequence of actions described. According to the disclosure, some steps may be performed in other orders or simultaneously. Besides, it will be appreciated by those skilled in the art that the embodiments described in the specification are optional embodiments, and the actions and modules involved are not necessarily essential to the disclosure.

In the foregoing embodiments, the elaboration of each embodiment has its own emphasis. For parts not described in detail in one embodiment, reference can be made to the relevant illustration in other embodiments.

It should be understood that, the apparatus disclosed in the embodiments provided in the disclosure may also be implemented in various other manners. For example, the above apparatus embodiments are merely illustrative, e.g., the division of units is only a division of logical functions, and other manners of division may be available in practice, e.g., multiple units or assemblies may be combined or may be integrated into another system, or some features may be ignored or skipped. In other respects, the coupling or direct coupling or communication connection as illustrated or discussed may be an indirect coupling or communication connection through some interface, apparatus, or unit, and may be electrical or otherwise.

Separated units as illustrated may or may not be physically separated. Components displayed as units may or may not be physical units, and may reside at one location or may be distributed to multiple networked units. Some or all of the units may be selectively adopted according to practical needs to achieve desired objectives of the disclosure.

In addition, various functional units described in various embodiments of the disclosure may be integrated into one processing unit or may be present as a number of physically separated units, and two or more units may be integrated into one. The integrated unit may be implemented in the form of hardware, or may be implemented in the form of software program module.

If the integrated unit is implemented in the form of software program module and sold or used as a standalone product, the integrated unit may be stored in a computer-readable memory. Based on such an understanding, the essential technical solution, or the portion that contributes to the related art, or part of the technical solution of the disclosure may be embodied as software products. The computer software product can be stored in a memory and may include multiple instructions that, when executed, can cause a computer device, e.g., a personal computer, a server, a network device, etc., to execute some or all operations of the methods described in various embodiments of the disclosure. The above memory may include various kinds of media that can store program codes, such as a universal serial bus (USB) flash disk, a read-only memory (ROM), a random access memory (RAM), a mobile hard drive, a magnetic disk, or an optical disk.

Those of ordinary skill in the art should understand that all or some of the steps of the methods in the foregoing embodiments may be implemented by programs instructing relevant hardware. The programs may be stored in a computer readable memory, and the memory may include a flash disk, a ROM, a RAM, a magnetic disk, or an optical disk.

The embodiments of the disclosure are described in detail above, and the principle and implementation of the disclosure are elaborated with reference to specific examples. The elaboration of the foregoing embodiments is only intended for facilitating understanding of the method and the core idea of the disclosure. In addition, those skilled in the art may make modifications to the specific implementation and application scope according to the idea of the disclosure. Therefore, the content of the specification shall not be construed as limitation to the disclosure.

What is claimed is:

1. A radio frequency power detection device, comprising:
a first microstrip line, wherein the first microstrip line is connected to a radio frequency power supply;
a second microstrip line, wherein the second microstrip line is disposed parallel to the first microstrip line and coupled to the first microstrip line, a predetermined point on the second microstrip line is grounded, and the predetermined point is used to indicate a physical isolation point of the second microstrip line;
a voltage detection unit, wherein the voltage detection unit is connected to one end of the second microstrip line and is configured to detect a voltage of the second microstrip line;
a capacitor unit, wherein the capacitor unit comprises a capacitor sub-unit and a control sub-unit, the capacitor sub-unit is connected to the control sub-unit, and the control sub-unit is configured to control an output capacitance value of the capacitor unit based on the capacitor sub-unit; the capacitor unit is connected to the first microstrip line and the second microstrip line, or the predetermined point on the second microstrip line is grounded through the capacitor unit; the capacitor unit is configured to select different capacitance values according to an actual distance between the first microstrip line and the second microstrip line, to make the actual distance between the first microstrip line and the second microstrip line equal to a preset distance between the first microstrip line and the second microstrip line; and
a distance testing unit, wherein the distance testing unit is connected to the capacitor unit and the voltage detection unit, and the distance testing unit is configured to detect a voltage at the predetermined point; the distance testing unit is configured to send a first distance signal to the control sub-unit based on the voltage at the predetermined point being greater than zero, send a second distance signal to the control sub-unit based on the voltage at the predetermined point being less than zero, and send a third distance signal to the voltage detection unit based on the voltage at the predetermined point being zero; wherein the first distance signal is used to indicate that the actual distance is less than the preset distance, the second distance signal is used to indicate that the actual distance is greater than the preset distance, and the third distance signal is used to indicate that the actual distance is equal to the preset distance.

2. The device of claim 1, wherein the capacitor sub-unit comprises a plurality of capacitors, and the plurality of capacitors are connected in parallel; the control sub-unit comprises at least one switch, the at least one switch is connected to each of the plurality of capacitors, and a connection state between each of the plurality of capacitors and the second microstrip line is controlled based on the at least one switch, wherein the connection state comprises a normal connection or a disconnection.

3. The device of claim 1, wherein based on the predetermined point on the second microstrip line being grounded through the capacitor unit, the capacitor sub-unit comprises a variable capacitor, the variable capacitor comprises a first electrode plate and a second electrode plate, and the first electrode plate and the second electrode plate are mutually insulated; and the first pole plate is grounded, and the control sub-unit is configured to control rotation of the first electrode plate to control a capacitance value of the variable capacitor.

4. The device of claim 3, wherein the control sub-unit comprises at least one capacitor adjuster, each of the at least one capacitor adjuster is connected to the variable capacitor, and the control sub-unit is configured to control rotation of the first electrode plate based on the at least one capacitor adjuster.

5. The device of claim 1, wherein the capacitor sub-unit comprises a programmable capacitor, the programmable capacitor is configured with a capacitance-value control logic, the control sub-unit is configured to generate a capacitance-value control signal according to the first distance signal or the second distance signal, and the programmable capacitor is configured to control a capacitance value of the programmable capacitor based on the capacitance-value control logic in response to the capacitance-value control signal.

6. The device of claim 3, wherein based on the capacitor unit being connected to the first microstrip line and the second microstrip line, the control sub-unit is configured to generate a first control strategy according to the first distance signal or the second distance signal;
based on the predetermined point on the second microstrip line being grounded through the capacitor unit, the control sub-unit is configured to generate a second control strategy according to the first distance signal or the second distance signal.

7. The device of claim 4, wherein based on the capacitor unit being connected to the first microstrip line and the second microstrip line, the control sub-unit is configured to generate a first control strategy according to the first distance signal or the second distance signal;
based on the predetermined point on the second microstrip line being grounded through the capacitor unit, the control sub-unit is configured to generate a second control strategy according to the first distance signal or the second distance signal.

8. The device of claim 5, wherein based on the capacitor unit being connected to the first microstrip line and the second microstrip line, the control sub-unit is configured to generate a first control strategy according to the first distance signal or the second distance signal;
based on the predetermined point on the second microstrip line being grounded through the capacitor unit, the control sub-unit is configured to generate a second control strategy according to the first distance signal or the second distance signal.

9. The device of claim 2, wherein a capacitance value of at least one capacitor in the plurality of capacitors is different from capacitance values of other capacitors.

10. A radio frequency power detection system, comprising a radio frequency power detection device and a radio frequency power supply;
wherein the radio frequency power supply is connected to the radio frequency power detection device;
wherein the radio frequency power detection device comprises:
a first microstrip line, wherein the first microstrip line is connected to the radio frequency power supply;
a second microstrip line, wherein the second microstrip line is disposed parallel to the first microstrip line and coupled to the first microstrip line, a predetermined point on the second microstrip line is grounded, and the predetermined point is used to indicate a physical isolation point of the second microstrip line;
a voltage detection unit, wherein the voltage detection unit is connected to one end of the second microstrip line and is configured to detect a voltage of the second microstrip line;
a capacitor unit, wherein the capacitor unit comprises a capacitor sub-unit and a control sub-unit, the capacitor sub-unit is connected to the control sub-unit, and the control sub-unit is configured to control an output capacitance value of the capacitor unit based on the capacitor sub-unit; the capacitor unit is connected to the first microstrip line and the second microstrip line, or the predetermined point on the second microstrip line is grounded through the capacitor unit; the capacitor unit is configured to select different capacitance values according to an actual distance between the first microstrip line and the second microstrip line, to make the actual distance between the first microstrip line and the second microstrip line equal to a preset distance between the first microstrip line and the second microstrip line; and
a distance testing unit, wherein the distance testing unit is connected to the capacitor unit and the voltage detection unit, and the distance testing unit is configured to detect a voltage at the predetermined point; the distance testing unit is configured to send a first distance signal to the control sub-unit based on the voltage at the predetermined point being greater than zero, send a second distance signal to the control sub-unit based on the voltage at the predetermined point being less than zero, and send a third distance signal to the voltage detection unit based on the voltage at the predetermined point being zero; wherein the first distance signal is used to indicate that the actual distance is less than the preset distance, the second distance signal is used to indicate that the actual distance is greater than the preset distance, and the third distance signal is used to indicate that the actual distance is equal to the preset distance.

11. The system of claim 10, wherein the capacitor sub-unit comprises a plurality of capacitors, and the plurality of capacitors are connected in parallel; the control sub-unit comprises at least one switch, the at least one switch is connected to each of the plurality of capacitors, and a connection state between each of the plurality of capacitors and the second microstrip line is controlled based on the at least one switch, wherein the connection state comprises a normal connection or a disconnection.

12. The system of claim 10, wherein based on the predetermined point on the second microstrip line being grounded through the capacitor unit, the capacitor sub-unit comprises a variable capacitor, the variable capacitor comprises a first electrode plate and a second electrode plate, and the first electrode plate and the second electrode plate are mutually insulated; and the first pole plate is grounded, and the control sub-unit is configured to control rotation of the first electrode plate to control a capacitance value of the variable capacitor.

13. The system of claim 12, wherein the control sub-unit comprises at least one capacitor adjuster, each of the at least one capacitor adjuster is connected to the variable capacitor, and the control sub-unit is configured to control rotation of the first electrode plate based on the at least one capacitor adjuster.

14. The system of claim 10, wherein the capacitor sub-unit comprises a programmable capacitor, the programmable capacitor is configured with a capacitance-value control logic, the control sub-unit is configured to generate a capacitance-value control signal according to the first distance signal or the second distance signal, and the programmable capacitor is configured to control a capacitance value of the programmable capacitor based on the capacitance-value control logic in response to the capacitance-value control signal.

15. The system of claim 12, wherein based on the capacitor unit being connected to the first microstrip line and the second microstrip line, the control sub-unit is configured to generate a first control strategy according to the first distance signal or the second distance signal;
based on the predetermined point on the second microstrip line being grounded through the capacitor unit, the control sub-unit is configured to generate a second control strategy according to the first distance signal or the second distance signal.

16. The system of claim 13, wherein based on the capacitor unit being connected to the first microstrip line and the second microstrip line, the control sub-unit is configured to generate a first control strategy according to the first distance signal or the second distance signal;
based on the predetermined point on the second microstrip line being grounded through the capacitor unit, the control sub-unit is configured to generate a second control strategy according to the first distance signal or the second distance signal.

17. The system of claim 14, wherein based on the capacitor unit being connected to the first microstrip line and the second microstrip line, the control sub-unit is configured to generate a first control strategy according to the first distance signal or the second distance signal;
based on the predetermined point on the second microstrip line being grounded through the capacitor unit, the control sub-unit is configured to generate a second control strategy according to the first distance signal or the second distance signal.

18. The system of claim 11, wherein a capacitance value of at least one capacitor in the plurality of capacitors is different from capacitance values of other capacitors.
